(19) United States
(12) Patent Application Publication
(10) Pub. No.: US 2005/0284653 A1
(43) Pub. Date: Dec. 29, 2005

(54) Condition display method and wiring board for wiring board design

(75) Inventor: Naofumi Okayama, Takefu-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD, Takefu-city (JP)

(21) Appl. No.: 11/157,822

(22) Filed: Jun. 22, 2005

(30) Foreign Application Priority Data
Jun. 23, 2004 (JP) 2004-184397

(51) Int. Cl. H05K 1/00

(52) U.S. Cl. 174/250

(57) ABSTRACT

When designing and arranging an electronic part such as a PC card connector on a wiring board using a CAD device, it is an object of the present invention to provide a condition display method for a wiring board design with excellent practicability capable of efficiently arranging other electronic parts lower than the height of a gap produced between the card connector and the underlying wiring board in the gap area. The method includes the steps of reading shape/size data of a PC card connector or the like producing a gap in an underlying part from an electronic parts catalog thereof, inputting gap area data and height limits which falls within an allowable height range in the gap area in a CAD menu of the wiring board design CAD device, thereby partitioning and displaying mountable areas with a height limit on a drawing of the wiring board with lines indicating the areas and displaying height limits of electronic parts that can be arranged in the mountable areas.

The present application is based on and claims priority of Japanese patent applications No. 2004-184397 filed on Jun. 23, 2004, the entire contents of which are hereby incorporated by reference.

### BACKGROUND OF THE INVENTION

1. Field of the Invention

The present invention relates to a design method for forming a wiring board using a CAD device or the like, and more particularly, to a technological field which effectively uses a gap produced below an electronic part such as a PC card connector arranged on a wiring board to facilitate an appropriate arrangement of the electronic part according to the gap height.

2. Description of the Related Art

In designing a wiring board on which a plurality of electronic parts are arranged, a wiring board design CAD device is conventionally widely used for the purpose of efficiently arranging electronic parts within a limited wiring board space. Under such a circumstance, when an electronic part such as a PC card connector is arranged on the wiring board, some gaps may be produced between the electronic part and the wiring board located below. However, when another electronic part lower than the height of the gap is arranged in the gap produced below between the electronic part and wiring board, the designer needs to follow complicated steps of holding the actual electronic part by hand, actually measuring the size of the step height of the back of the electronic part which produces the gap, converting it to a gap height and selecting and arranging other electronic parts which are mountable in the gap and lower than the gap height.

As such a wiring board design method using a CAD device, for example, the following conventional technologies are known. Japanese Patent Laid-Open Publication No. 2000-331060 presents the following apparatus to support the design for arranging an insertion type part which has a lead wire penetrating a printed board 10, one side of which is used as a parts surface and the other side of which is used as a soldering surface, from the parts surface and coming out of the soldering surface, which is then bent and soldered, and a surface mount type part 34 mounted on the soldering surface side. As shown in FIG. 5, this is a printed board parts arrangement design supporting apparatus including, around a surface mount type part 34 placed on the soldering surface side, prohibited area setting means for setting a surface mount process prohibited area 36 and an insertion process prohibited area 37 based on a predetermined relationship with respect to an outline 35 of the surface mount type part and display means for deciding whether positions of the outline 35 of another surface mount type part 34 or lead wires of insertion type parts invade the surface mount process prohibited area 36 or insertion process prohibited area 37 set by the prohibited area setting means or not and displaying the decision result as an image, and sets a surface mount process prohibited area 36 which prohibits the mounting of the other surface mount type part 34 around the surface mount type part 34 mounted on the soldering surface side based on the part outline or the like. Furthermore, the insertion process prohibited area 37 is set in such a way that the operation of an insertion tool for carrying out treatment of the lead wires of the insertion parts does not interfere with the surface mount part 34 and that the extension of the prohibited area is changed according to the height of the surface mount type part 34. Furthermore, for the insertion type parts, the insertion process prohibited area 37 is set according to the insertion tool for carrying out treatment of the lead wires, the surface mount process prohibited area 36 is set according to the height of the surface mount type part 34 in connection with the operation, the presence/absence of an invasion between the respective prohibited areas is checked and violating locations are displayed with colors and highlighted lines. Even when parts are mounted on the printed board in difference processes, this makes it possible to check the presence/absence of an invasion using a CAD device or the like. However, the contents presented in the aforementioned Japanese Patent Laid-Open Publication No. 2000-331060 cannot be said to be an device that includes design supporting means for arranging other electronic parts lower than the gap height in the gap produced below the electronic part arranged on the printed board 10.

Furthermore, Japanese Utility Model Laid-Open Publication No. 64-48065 describes that marks indicating allowable mounting heights of electronic parts are provided on the surface of a mounting board, the height marks are expressed by lines partitioning the surface of the mounting board as the areas where electronic parts having a predetermined height or less are mounted and the height marks are expressed by numerical values indicating the allowable mounting heights of electronic parts. Furthermore, in addition to the height marks indicating the area where electronic parts having a predetermined height or less are mounted by lines which partition the surface of the mounting board, a method of expressing the height marks with numerical values indicating allowable mounting heights of electronic parts within the respective areas is presented, but the method described in Japanese Utility Model Laid-Open Publication No. 64-48065 is intended for the process of mounting electronic parts while confirming height limits displayed in the mounting stage and cannot be said as the method for supporting the designer in the design stage.

According to the conventional technology, when an electronic part such as a PC card connector is arranged on the wiring board, some gaps may be produced between the electronic part and the underlying wiring board and when another electronic part lower than the gap height is arranged in the gap between the electronic part producing the gap below and underlying wiring board, the designer needs to follow complicated steps of holding the actual electronic part by hand, actually measuring the size of the step height of the back of the electronic part which produces the gap, converting it to a gap height and selecting and arranging other electronic parts which are mountable in the gap and lower than the gap height. Furthermore, in order to select and arrange electronic parts in the area where the heights of electronic parts to be mounted are restricted using a wiring board design CAD device, it is a general practice to change part of the program of the wiring board design CAD device and such a change of the program is one of the factors increasing the cost. Furthermore, the wiring board includes at least an area where both circuit wiring and mounting are prohibited, an area where mounting is prohibited and an area where limited mounting is allowed, and it is necessary to display these partitions in a visually recognizable manner in the stage of designing the wiring board and display height limits in the area where limited mounting is allowed. The present specification describes the area where both circuit wiring and mounting are prohibited as a circuit wiring prohibited/mounting prohibited area.

In conducting a circuit design of a wiring board using a wiring board design CAD device or the like, it is an object of the present invention to provide a design supporting method for a wiring board with excellent practicability capable of making full use of a design support function of an existing wiring board design CAD device, especially effectively using gaps produced below electronic parts such as a PC card connector arranged on the wiring board and facilitating appropriate arrangement of electronic parts according to the gap heights and provide an electronic apparatus which realizes high-density mounting on a wiring board using this wiring board design method.

### BRIEF SUMMARY OF THE INVENTION

The condition display method for a wiring board design according to a first aspect of the invention is a method of forming a wiring board, comprising a step of arranging electronic parts or the like on a mounting surface of the wiring board on which a circuit is formed using a wiring board design CAD device, in which, based on size data such as an electronic part arranged on the wiring board, data of mountable areas with a height limit where mounting of other electronic parts is allowed below the electronic part, height limit data of mounting parts corresponding to the height of a gap produced below the electronic part, data of areas where mounting of electronic parts or the like is prohibited and data of circuit wiring prohibited/mounting prohibited areas, the mountable areas with a height limit where electronic parts can be mounted within at least the height limit data, areas where mounting of electronic parts or the like is prohibited and circuit wiring prohibited/mounting prohibited areas are partitioned and displayed in a visually recognizable manner.

The structure of the first aspect of the invention is a condition display method for a wiring board design in which, based on size data such as an electronic part arranged on the wiring board, data of mountable areas with a height limit where mounting of other electronic parts is allowed below the electronic part, height limit data of mounting parts corresponding to the height of a gap produced below the electronic part, data of areas where mounting of electronic parts or the like is prohibited and data of circuit wiring prohibited/mounting prohibited areas, the mountable areas with a height limit where electronic parts can be mounted within at least the height limit data, areas where mounting of electronic parts or the like is prohibited and circuit wiring prohibited/mounting prohibited areas are partitioned and displayed in a visually recognizable manner, and therefore the designer can recognize that the gap area includes mountable areas with a height limit where electronic parts within the height limit can be mounted, mounting prohibited areas and circuit wiring prohibited/mounting prohibited areas while observing the displayed drawing being created.

A second aspect of the invention is a condition display method for a wiring board design in which in the gap area, the mountable areas with a height limit are partitioned per predetermined height limit and displayed with a numerical value indicating the height limit added.

According to the structure of the second aspect of the invention, in the gap area, the mountable areas with a height limit are partitioned per predetermined height limit and displayed with a numerical value indicating the height limit added, and therefore the designer can observe numerical values indicating height limits displayed in the mountable areas with a height limit on the drawing being created which is displayed on the wiring board design CAD device to thereby select and arrange electronic parts within the height limit that can be actually mounted appropriately.

The wiring board according to a third aspect of the invention is a wiring board on which a circuit is formed, comprising an electronic part or the like arranged on a mounting surface thereof, in which mountable areas with a height limit where mounting of electronic parts within a height limit is allowed, areas where mounting of electronic parts or the like is prohibited and circuit wiring prohibited/mounting prohibited areas are partitioned and displayed on the wiring board using silk printing or the like in a visually recognizable manner.

According to the structure of the third aspect of the invention, mountable areas with a height limit where mounting of electronic parts within a height limit is allowed, areas where mounting of electronic parts or the like is prohibited and circuit wiring prohibited/mounting prohibited areas are partitioned and displayed on the wiring board using silk printing or the like in a visually recognizable manner, and therefore even in the mounting process on the wiring board, it is possible to recognize that the gap area of the wiring board includes mountable areas with a height limit where mounting of electronic parts within a height limit is allowed, mounting prohibited areas and circuit wiring prohibited/mounting prohibited areas.

A fourth aspect of the invention is a wiring board in which in the gap area, the mountable areas with a height limit are partitioned per predetermined height limit and displayed with a numerical value indicating a height limit added on the wiring board using silk printing or the like.

According to the structure of the fourth aspect of the invention, the mountable areas with a height limit are partitioned per predetermined height limit and displayed with a numerical value indicating a height limit added on the wiring board using silk printing or the like, and therefore it is possible to check the height limit of the mountable areas with a height limit by observing the wiring board even in the mounting process on the wiring board.

The structure of the first aspect of the invention is a condition display method for a wiring board design in which, based on size data such as an electronic part arranged on the wiring board, data of mountable areas with a height limit where mounting of other electronic parts is allowed below the electronic part, height limit data of mounting parts corresponding to the height of a gap produced below the electronic part, data of areas where mounting of electronic parts or the like is prohibited and data of circuit wiring prohibited/mounting prohibited areas, the mountable areas with a height limit where electronic parts can be mounted within at least the height limit data, areas where mounting of electronic parts or the like is prohibited and circuit wiring prohibited/mounting prohibited areas are partitioned and displayed in a visually recognizable manner, and therefore the designer can recognize that the gap area includes mountable areas with a height limit where electronic parts within the height limit can be mounted, mounting prohibited areas and circuit wiring prohibited/mounting prohibited areas while observing the displayed drawing being created, select and arrange electronic parts within the height limit based on the limits and prohibited conditions displayed in the gap area and thereby carry out circuit wiring, and can thereby design the wiring board efficiently and appropriately, effectively use the gap area between the electronic parts producing the gap below and the wiring board and realize high-density mounting of the wiring board.

According to the structure of the second aspect of the invention, in the gap area, the mountable areas with a height limit are partitioned per predetermined height limit and displayed with a numerical value indicating the height limit added, and therefore the designer can observe numerical values indicating height limits displayed in the mountable areas with a height limit on the drawing being created which is displayed on the wiring board design CAD device to thereby select and arrange electronic parts within the height limit that can be actually mounted appropriately. This can prevent the situation in the conventional example in which in front of the electronic part which produces the gap in the underlying part arranged on the drawing being created displayed on the wiring board design CAD device, the designer needs to follow complicated steps of actually measuring the step height of the electronic part which produces the gap, converting it to a gap height and selecting and arranging the other electronic parts which are mountable in the gap and lower than the gap height, and also eliminates the necessity for changing part of the program of the wiring board design CAD device in order to select and arrange electronic parts corresponding to the limited height using the wiring board design CAD device, which also avoids a cost increase due to the change of the program.

According to the structure of the third aspect of the invention, mountable areas with a height limit where mounting of electronic parts within a height limit is allowed, areas where mounting of electronic parts or the like is prohibited and circuit wiring prohibited/mounting prohibited areas are partitioned and displayed on the wiring board using silk printing or the like in a visually recognizable manner, and therefore even in the mounting process on the wiring board, it is possible to recognize that the gap area of the wiring board includes mountable areas with a height limit where mounting of electronic parts within a height limit is allowed, mounting prohibited areas and circuit wiring prohibited/mounting prohibited areas, and therefore it is possible to clarify setups of the mounting process, for example, mounting electronic parts that satisfy the height limit in the mountable areas with a height limit first and then mounting electronic parts producing a gap in the underlying part.

According to the structure of the fourth aspect of the invention, the mountable areas with a height limit are partitioned per predetermined height limit and displayed with a numerical value indicating a height limit added on the wiring board using silk printing or the like, and therefore it is possible to check the height limit of the mountable areas with a height limit by observing the wiring board even in the mounting process on the wiring board and also check the heights or the like of the electronic parts provided to be mounted in the area.

### BRIEF DESCRIPTION OF THE DRAWINGS

FIG. 1 is an illustrative side view showing a gap area produced below an electronic part mounted on a wiring board illustrating an embodiment of the present invention;

FIG. 2 is an illustrative top plan view of the electronic part which produces a gap in an underlying part illustrating the embodiment of the present invention;

FIG. 3 shows a mountable area with a height limit displayed on a wiring board design CAD device and a display example of numerical values indicating the height limit illustrating the embodiment of the present invention;

FIG. 4 illustrates silk printing on a wiring board 10 on which parts are arranged according to a partition and display of the mountable area with a height limit illustrating the embodiment of the present invention; and

FIG. 5 illustrates a setting condition of a conventional basic prohibited area.

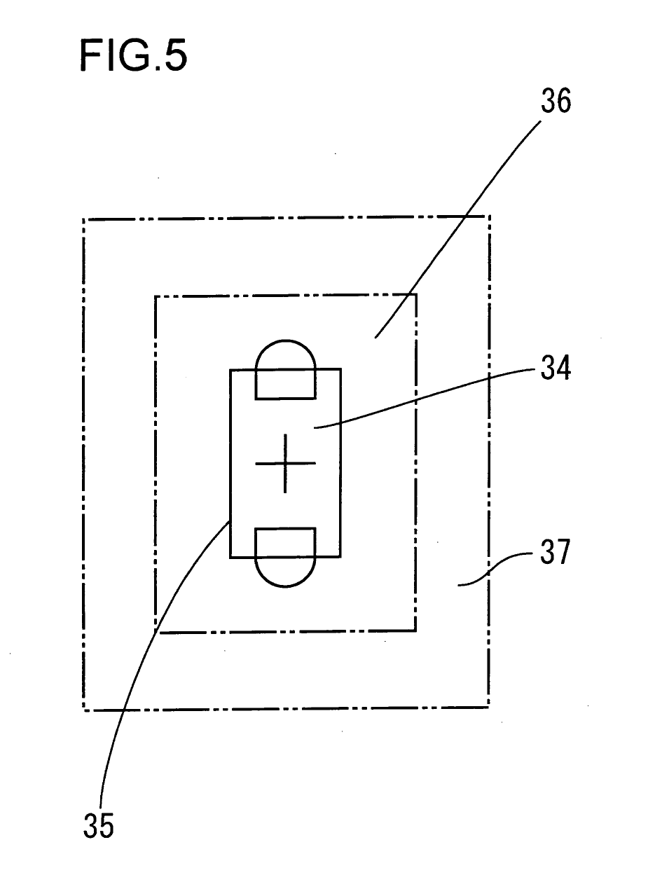

### DETAILED DESCRIPTION OF THE PREFERRED EMBODIMENTS

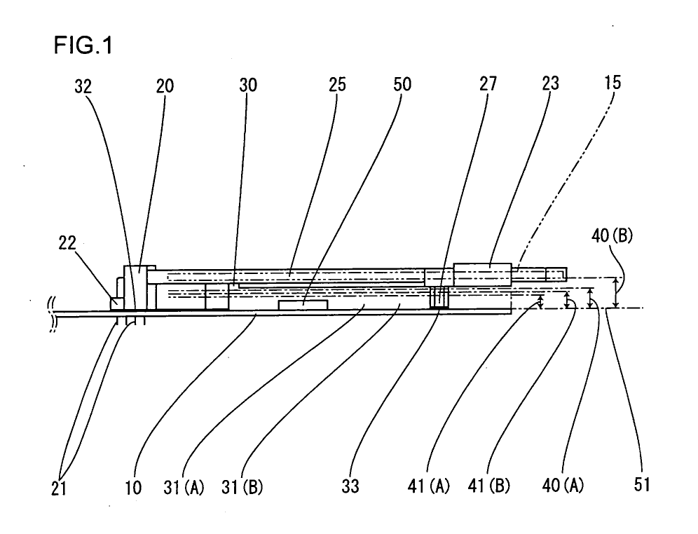

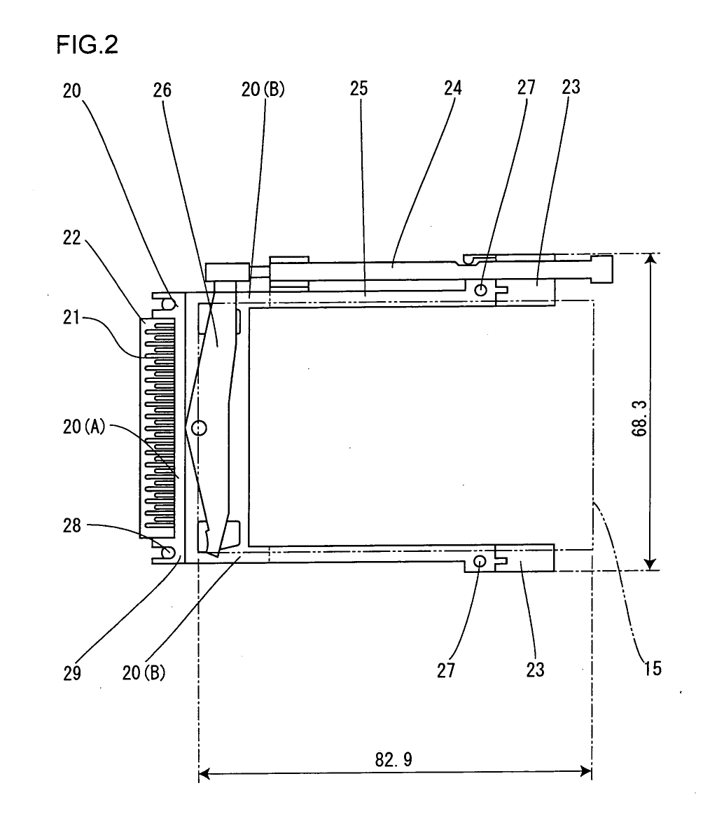

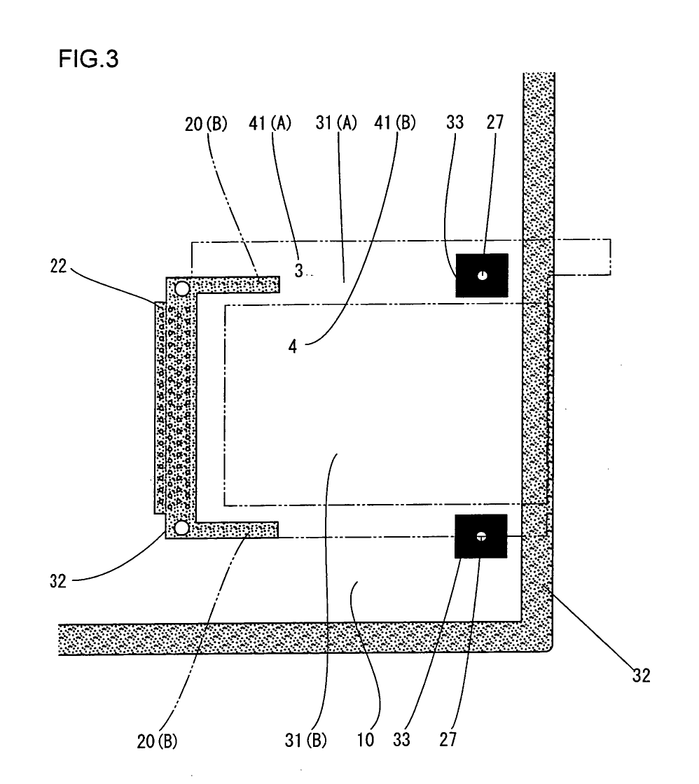

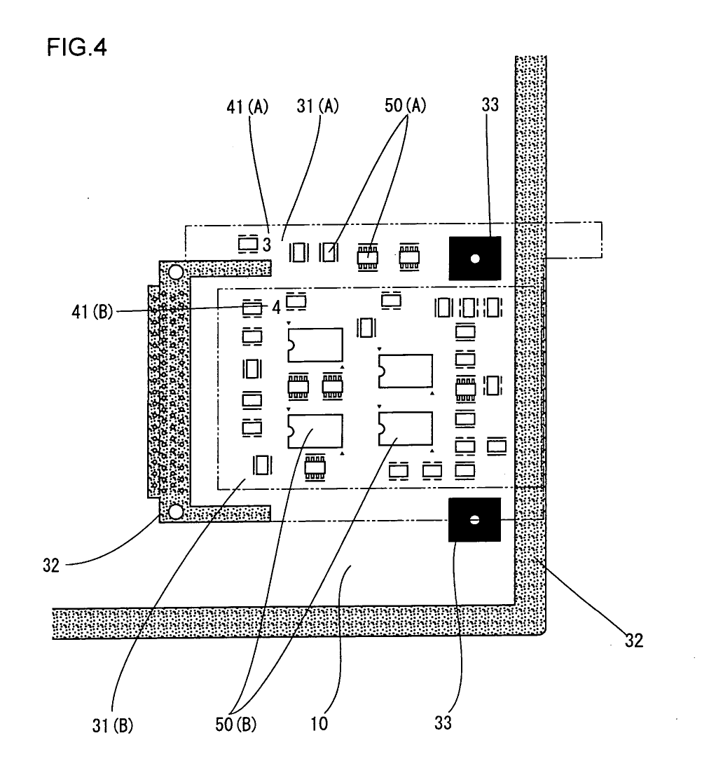

FIG. 1 is an illustrative side view of a gap area produced below an electronic part mounted on a wiring board illustrating an embodiment of the present invention and FIG. 2 is an illustrative top plan view of the electronic part which produces a gap in an underlying part illustrating the embodiment of the present invention. Furthermore, FIG. 3 shows a mountable area with a height limit displayed on a wiring board design CAD device and a display example of numerical values indicating the height limit illustrating the embodiment of the present invention and FIG. 4 illustrates silk printing on a wiring board 10 on which parts are arranged according to a partition and display of the mountable area with a height limit illustrating the embodiment of the present invention.

First, with reference to FIG. 2, a PC card connector 20 will be explained below as an example of an electronic part 20 which produces a gap in an underlying part.

The PC card connector 20 shown in FIG. 2 has substantially a horseshoe shape and this large substantially horseshoe-shaped concave portion is an area into which a PC card 15 is loaded. A pair of right and left supporting parts 20(B) to be fixed to the wiring board 10 are formed at both edges of a connector base 20(A) thereof and nuts 28 are attached to the respective supporting parts from a housing section 29. Furthermore, the connector base 20(A) is provided with a plurality of contact terminals 21 arranged in order, a socket (not shown) of the PC card 15 and the card connector 20 are connected at one end thereof and the plurality of contact terminals 21 are bent in an L-figure form in the direction of the wiring board 10 and connected to the wiring board 10 through through-holes of a locator section 22 supported and fixed to the connector base 20(A). Furthermore, the card connector 20 is provided with a pair of guide bar sections 23 formed projecting from the right and left sides to support both sides of the PC card 15 loaded from both ends of the connector base 20(A), and the connector base 20(A) and the guide bar sections 23 are connected and fixed by a metal frame 25. Furthermore, eyelets with a nut 27 are attached to tips of the pair of guide bar sections 23 and can be fixed to the wiring board 10 using a screw. Furthermore, a push bar 24 is provided on a side of one guide bar section 23 to draw out the PC card 15 loaded and since the push bar 24 is connected to one end of a revolving arm 26 which is fixed to the metal frame 25 in a freely rotatable manner, pushing the push bar 24 causes the revolving arm 26 to move in the rotation direction to allow the PC card 15 to be drawn out.

When this PC card connector 20 is attached to the wiring board 10, the supporting parts 20(B) of the card connector 20, the locator section 22 and the eyelets with a nut 27 disposed on the guide bar sections 23 are parts that directly contact the wiring board 10 and have surfaces contacting the wiring board 10 and those contacting surfaces constitute mounting prohibited areas 32 where no other electronic parts can be mounted. Especially, the eyelets with a nut 27 are metallic and fixed to the wiring board 10 using screws in direct contact therewith, hence constituting circuit wiring prohibited areas where no circuit wiring is allowed. Therefore, the surfaces of the wiring board 10 with which the supporting parts 20(B) of the connector 20 and the locator section 22 contact constitute the mounting prohibited areas 32 and the surfaces of the wiring board 10 with which the eyelets with a nut 27 contact constitute circuit wiring prohibited/mounting prohibited areas 33. Furthermore, except the above described two prohibited areas, the remaining areas which constitute parts below the PC card connector 20 when the PC card 15 is assumed to be mounted have a total width on the insertion slot side of the PC card 15 (6.83 cm)×depth of the PC card (8.29 cm)=56.6 cm² and a gap between the wiring board 10 and the PC card connector 20 is secured in this area, and any electronic part having a gap height 40 or less constitutes a mountable area with a height limit 31 where mounting is allowed.

Next, a gap area 30 produced between the wiring board 10 and PC card connector 20 when the PC card connector 20 is placed on the wiring board 10 will be explained below with reference to the side view when the PC card connector shown in FIG. 1 is mounted on the wiring board and the plan view of the PC card connector shown in FIG. 2.

As shown in FIG. 1 and FIG. 2, when the PC card 15 is loaded into the PC card connector 20, of the areas which constitute the underlying parts thereof, the surfaces of the wiring board 10 with which the supporting parts 20(B) and the locator section 22 of the card connector 20 have contact are the mounting prohibited areas 32, while the surfaces of the wiring board 10 with which the eyelets with a nut 27 provided for the guide bar 23 have contact are the circuit wiring prohibited/mounting prohibited areas 33. Furthermore, except the above described two types of prohibited areas, for the remaining areas which become the underlying parts of the PC card connector 20 when the PC card 15 is loaded, the gap area 30 is secured between them and the wiring board 10 as shown in FIG. 1 and the gap area 30 can constitute the mountable area with a height limit 31 where any electronic part 50 having the above described gap height or less can be mounted. By setting a height limit 41 including a certain amount of space with respect to the gap height 40 at this time, it is possible to place the electronic part 50 having a height equivalent to or less than this height limit 41 thus satisfying the height limit and prevent the electronic part 50 placed in this gap area 30 from contacting the PC card connector 20 or PC card. This can be expressed by the following expression: gap height 40>height limit 41≧height of electronic part 50 that satisfies height limit. This will be explained in further detail with reference to FIG. 1. In the mountable area with a height limit 31, the guide bars 23 of the PC card connector 20 are provided with guide rails for loading the PC card 15 in the form of grooves corresponding to the thickness of the PC card 15 and the height of a gap B 40(B) between the bottom surface of the PC card 15 loaded here and the wiring board 10 is 6 mm, which is higher by an amount corresponding to the thickness of the guide rails. Therefore, the height of a gap A 40(A) which becomes the underlying part of the guide bars 23 of the PC card connector 20 and the push bar 24 is 5 mm, which is lower than the height of the gap B 40(B), and it is possible to divide the underlying part into two areas for use; the area which becomes the underlying part of the PC card connector 20 and the area which becomes the underlying part of the PC card 15, having different gap heights. In FIG. 1, a certain amount of space is provided between the bottom surface of the PC card 15 and the wiring board 10, and since the B height limit 41(B) corresponding to the height of the gap B of 6 mm is set to 4 mm and the A gap height 40(A) which becomes the underlying part of the guide bar 23 of the PC card connector 20 and the push bar 24 is set to 5 mm, the A height limit 41(A) is set to 3 mm.

Next, the data of the PC card connector 20 which is an electronic part producing a gap in the underlying part is input to the wiring board design CAD device and a display example of numerical values indicating the mountable area with a height limit 31 and height limit 41 displayed will be explained with reference to FIG. 3 below.

When the designer places the electronic part 50 that satisfies the height limit within which it can be placed in the gap area 30 below the PC card connector 20 placed on the wiring board 10, the designer inputs shape/size data about a planar arrangement with reference to a shape/size diagram described in the catalog of the card connector 20 and a shape/size diagram assuming the case where the PC card 15 is loaded into the card connector 20, places and displays contours of the card connector 20 at predetermined positions of the drawing which displays the wiring board 10 being created. At this time, the end of the push bar 24 which is part of the PC card connector 20 is in the area protruding out of the housing of the electronic apparatus and the drawing depicts some of the contours sticking out of the wiring board 10.

Next, of the areas which become the underlying part of the card connector 20, the surfaces of the wiring board 10 with which the supporting parts 20(B) and the locator section 22 of the card connector 20 have contact and the periphery of the wiring board 10 are the mounting prohibited areas 32 where mounting of electronic parts or the like is prohibited and are displayed with lines indicating partitions and shading on the drawing being created together with the circuit wiring prohibited/mounting prohibited area 33 of the surfaces of the wiring board 10 which contact the eyelets with a nut 27. At this time, except the above described two types of prohibited areas, for the remaining area which becomes the underlying part of the PC card connector 20 assuming that the PC card 15 is loaded, the gap area 30 is secured between the wiring board 10 and the PC card connector 20, which constitutes the mountable area with a height limit 31 where the electronic part 50 that satisfies the height limit equal to or below the gap height can be mounted. This area has a certain difference between the underlying part of the PC card 15 and the underlying part of the PC card connector 20. While the gap height of the underlying part of the PC card connector 20 is 5 mm, a gap height of 6 mm is secured for the underlying part of the PC card 15 in the overall area. This embodiment provides the mountable area with a height limit 31 where the designer can realize two types of mounting due to the difference in this gap height, displays partition lines indicating the mountable area with a height limit 31 with a type of line different from the normal type and thereby displays the partitions in a visually recognizable manner.

Next, for the two types of mountable areas with a height limit 31, assuming that the step height of 5 mm of the back of the card connector 20 with respect to a mounting reference surface 51 when mounted on the wiring board 10 shown in FIG. 1 is the A gap height 40(A) and the step height of 6 mm between the back of the PC card 15 when the PC card 15 is loaded and the mounting reference surface 51 is the B gap height 40(B) these heights are read from the shape/size diagram described in the catalog of the PC card connector 20, and assuming that the step heights, that is, the A height limit 41(A) and the B height 41(B) set to be slightly lower than the gap height 40(A) and the B gap height 40(B) are 3 mm and 4 mm respectively, they are input to a CAD menu of the wiring board design CAD device and displayed within the A mountable area with a height limit 31(A) and B mountable area with a height limit 31(B) as the A height limit 41(A) of 3 mm and B height limit 41(B) of 4 mm. This can prevent the situation in the conventional example in which there is no means for displaying what kind of gaps are produced in the underlying part and the designer needs to follow complicated steps of holding by hand the part which produces a gap in the underlying part arranged on a drawing being created and displayed on the wiring board design CAD device, actually measuring the size of the step height of the back of the electronic part which produces the gap, converting it to a gap height and selecting and arranging other electronic parts which are mountable in the gap and lower than the gap height.

Through the above described procedure, it is possible to partition and display a plurality of mountable areas with a height limit 31(A), 31(B) with different types of lines by making full use of the design support function of the existing wiring board design CAD device and display the respective height limits, and the designer can thereby recognize that the gap area 30 constitutes the mountable areas with a predetermined height limit 31(A), 31(B) where electronic parts 50(A), 50(B) within different height limits can be mounted according to the height limits 41(A), 41(B), and select and arrange the electronic parts 50(A), 50(B) within the height limits in the gap area 30 while observing the displayed drawing being created and carry out circuit wiring, and can thereby efficiently design the wiring board 10 on which the electronic part 50 corresponding to the gap height 40 is selected and arranged appropriately, effectively use gaps produced below the electronic part 20 to arrange the other electronic part 50. Thus, it is possible to realize much higher density mounting on the wiring board 10, arrange the other electronic part 50 in the gap produced below the electronic part 20 by making full use of the design support function of the existing wiring board design CAD device, which eliminates the necessity for changing part of the program of the wiring board design CAD device and eliminates the necessity for costs and man power required to change the program.

Next, an embodiment of silk printing on the wiring board 10 on which parts are arranged according to the partition and display of the displayed mountable areas with a height limit will be explained with reference to FIG. 4.

In FIG. 4 of this embodiment, it is difficult to understand what kind of electronic parts are arranged below the PC card connector 20 from the display of silk printing alone, and therefore FIG. 4 describes as if the electronic parts are mounted in the mountable areas with a height limit. On the surface of the wiring board 10, partition lines indicating the mountable areas with a height limit of the gap area produced below of the PC card connector 20 and the height limits 41 corresponding to the respective mountable areas 31 are printed and displayed with silk printing, and the periphery of the wiring board and the two mounting prohibited areas 32 of the surfaces of the wiring board 10 with which the supporting parts 20(B) and locator section 22 of the card connector 20 have contact are printed and displayed with shading or the like and the circuit wiring prohibited/mounting prohibited areas 33 are printed and displayed solidly filled with a color. Furthermore, in the A mountable area with a height limit 31(A) of the back of the PC card connector 20, chip resistors or the like that satisfy the A height limit 41(A) of 3 mm are arranged and graphics or the like indicating the types of the parts are silk-printed. Furthermore, in the B mountable area with a height limit (B) which becomes the back of the PC card 15, a plurality of electronic parts 50 such as ICs that satisfy the B height limit 41(B) of 4 mm are efficiently arranged and graphics or the like indicating the types of the parts are silk-printed.

As described above, according to this embodiment, the condition display method in the wiring board design of the present invention includes the steps of reading step heights of the wiring board 10 with respect to the mounting reference surface 51 in the gap area 30 produced below the electronic part 20 from the shape/size diagram described in the catalog of the electronic part 20, inputting the gap area 30 and the height limit 41 which is the step height converted to a height limit corresponding to the gap height 40 to a CAD menu of the wiring board design CAD device and thereby partitioning and displaying the mountable area with a height limit 31 where the electronic parts 50 within the height limit 41 which falls within the range of the gap height 40 of the gap area 30 can be mounted in a visually recognizable manner by making full use of the design support function of the existing wiring board design CAD device and displaying the height limit 41 in the partitioned and displayed mountable area with a height limit 31 with a numerical value, and therefore the designer can recognize that the gap area 30 is the mountable area with a height limit 31 where the electronic parts 50 within the height limit can be mounted while viewing the drawing displayed on the wiring board design CAD device, select and arrange the electronic parts 50 within the height limit and carry out circuit wiring, and can thereby efficiently design the appropriate wiring board 10 and effectively use the gap area 30 between the electronic part 20 and the wiring board 10 produced in the underlying part to realize high-density mounting of the wiring board 10. Furthermore, it is possible to eliminate the situation as shown in the conventional example in which it is difficult to understand what kind of gaps are produced below the electronic part 20 and in front of the electronic part 20 which produces the gap in the underlying part arranged on the drawing being created displayed on the wiring board design CAD device, the designer needs to follow complicated steps of actually measuring the step height of the electronic part 20 which produces the gap, converting it to a gap height 40 and selecting and arranging the other electronic parts 50 which are mountable in the gap and lower than the gap height, and therefore the present invention can be said to be the design supporting method for the wiring board 10 with excellent practicability and also eliminates the necessity for changing part of the program of the wiring board design CAD device by making full use of the design support function of the existing wiring board design CAD device and eliminates the necessity for costs and man power required to change the program. Furthermore, by silk-printing and displaying the prohibited areas, mountable areas with a height limit and height limits on the wiring board, it is possible to facilitate setups of processes in the mounting process of the electronic parts, check the electronic parts and prevent unnecessary quality trouble beforehand.

This embodiment has been explained in detail so far, but the present invention is not limited to the above described embodiment and can be implemented modified in various ways within the scope of the essence of the present invention. For example, the electronic part 20 which produces a gap in its underlying part is not limited to a PC connector, but can also be a device which produces a gap in its underlying part such as a DVD device or HDD device incorporated in an electronic apparatus or an electronic device mounted on the wiring board 10 which produces a gap in its underlying part on the wiring board 10. Furthermore, means for partitioning and displaying mountable areas with a height limit can be not only different types of lines but also shading applied to the relevant areas to facilitate visual recognition and in this way, the designer changes the means in consideration of ease of use when designing the wiring board 10, and the means is therefore not limited to the aforementioned embodiment but can be selected as appropriate.

1. A condition display method for a wiring board design which is a method of forming a wiring board, comprising a step of arranging electronic parts or the like on a mounting surface of the wiring board on which a circuit is formed using a wiring board design CAD device,
wherein, based on size data such as an electronic part arranged on the wiring board, data of mountable areas with a height limit where mounting of other electronic parts is allowed below the electronic part, height limit data of mounting parts corresponding to the height of a gap produced below the electronic part, data of areas where mounting of electronic parts or the like is prohibited and data of circuit wiring prohibited/mounting prohibited areas, the mountable areas with a height limit where electronic parts can be mounted within at least the height limit data, areas where mounting of electronic parts or the like is prohibited and circuit wiring prohibited/mounting prohibited areas are partitioned and displayed in a visually recognizable manner.

2. The condition display method for a wiring board design according to claim 1, wherein in the gap area, the mountable areas with a height limit are partitioned per predetermined height limit and displayed with a numerical value indicating the height limit added.

3. A wiring board on which a circuit is formed, comprising an electronic part or the like arranged on a mounting surface thereof, wherein mountable areas with a height limit where mounting of electronic parts within a height limit is allowed, areas where mounting of electronic parts or the like is prohibited and circuit wiring prohibited/mounting prohibited areas are partitioned and displayed on the wiring board using silk printing or the like in a visually recognizable manner.

4. The wiring board according to claim 3, wherein in the gap area, the mountable areas with a height limit are partitioned per predetermined height limit and displayed with a numerical value indicating the height limit added on the wiring board using silk printing or the like.
